(19) United States
(12) Patent Application Publication
(10) Pub. No.: US 2018/0277781 A1
(43) Pub. Date: Sep. 27, 2018

(54) LIGHT-EMITTING DEVICE AND DISPLAY DEVICE

(71) Applicant: SHENZHEN CHINA STAR OPOELECTRONICS TECHNOLOGY CO., LTD., Shenzhen, Guangdong (CN)

(72) Inventor: Lixuan CHEN, Shenzhen, Guangdong (CN)

(73) Assignee: Shenzhen China Star Optoelectronics Technology Co., Ltd., Shenzhen, Guangdong (CN)

(21) Appl. No.: 15/523,370

(22) PCT Filed: Mar. 30, 2017
(86) PCT No.: PCT/CN2017/078799

§ 371 Date: Apr. 29, 2017

(30) Foreign Application Priority Data
Feb. 20, 2017 (CN) 201710088695.7

(51) Int. Cl. H01L 51/50; H01L 27/32; H01L 51/52; H01L 51/00

(52) U.S. Cl. CPC H01L 51/502; H01L 27/3246; H01L 51/5218; H01L 51/0005; H01L 51/5056; H01L 51/5072; H01L 51/5092; H01L 51/5234

(57) ABSTRACT

A light-emitting device and display device are disclosed. The light-emitting device includes: a substrate; a limitation block disposed on the substrate for defining a light-emitting region; a bottom electrode disposed on the substrate and located in the light-emitting region, wherein a gap is existed between the bottom electrode and the limitation block; a light-emitting component disposed on the bottom electrode; and a top electrode disposed on the light-emitting component. Through forming a gap among the bottom electrode, the top electrode and the limitation block, an uneven thickness region of each function layer of the light-emitting component is not located between the bottom electrode and the top electrode which are overlapped in space. Accordingly, a carrier flow having a higher current density will not pass through the uneven thickness region of each function layer so that the light-emitting property of the pixel will not be affected.

### BACKGROUND OF THE INVENTION

### 1. Field of the Invention

The present invention relates to a display technology field, and more particularly to a light-emitting device and display device.

### 2. Description of Related Art

Inkjet printing has a high material utilization rate, and does not require a high precision mask so that the inkjet printing has been considered as a display manufacturing technology having high potential.

When adopting the inkjet printing method to manufacturing an OLED display, an unavoidable problem is an edge climbing problem when a solution is on a pixel definition layer. The inkjet printing method belongs to a wet film forming art. After a solution is dropped, a solvent should be evaporated in order to dry and form a film. The drying process usually generates difference in film forming property (such as roughness, thickness and uniformity, etc.) The process of adopting the inkjet printing method to manufacture an OLED display device is: on a substrate provided with a conductive electrode, manufacturing a pixel definition layer through a lithography process, and forming a structure like a container between the pixel definition layer and the substrate. Because the pixel definition layer usually adopts a hydrophobic material having a single layer or multiple layers, the solution will generate a convex status at middle portion depending on surface tension.

After dropping an ink, through a solvent evaporation process, an organic function layer is formed. In the film forming process of the organic function layer, a pinning effect is generated. That is, an uneven phenomenon of a film thickness at the interface and a film thickness at the center. The solution will generate an edge climbing phenomenon such that the film is thin at the middle portion and thick at the edge portion so as to affect the film forming quality and the uniformity of the emitting of the pixel.

### SUMMARY OF THE INVENTION

In order to solve the above technology problem, the purpose of the present invention is to provide a light-emitting device, comprising: a substrate; a limitation block disposed on the substrate and used for defining a light-emitting region; a bottom electrode disposed on the substrate and located in the light-emitting region, wherein a gap is existed between the bottom electrode and the limitation block; a light-emitting component disposed on the bottom electrode; and a top electrode disposed on the light-emitting component.

Optionally, a projection of the top electrode projected on the bottom electrode is within the bottom electrode.

Optionally, from the bottom electrode to the top electrode, the light-emitting component sequentially includes: a hole injection layer, a hole transport layer, a light-emitting layer, an electron transport layer and an electron injection layer.

Optionally, from the bottom electrode to the top electrode, the light-emitting component sequentially includes: a hole injection layer, a hole transport layer, a light-emitting layer, an electron transport layer and an electron injection layer.

Optionally, the light-emitting layer is an organic light-emitting layer or a quantum dot light-emitting layer.

Optionally, the light-emitting layer is an organic light-emitting layer or a quantum dot light-emitting layer.

Optionally, one of the bottom electrode and the top electrode is transparent or translucent, and the other of the bottom electrode and the top electrode is non-transparent and reflective.

Optionally, the hole injection layer and/or the hole transport layer and/or the light-emitting layer and/or the electron transport layer and/or the electron injection layer are made of inkjet printing method.

Optionally, the limitation block is made of a hydrophobic material.

Another purpose of the present invention is to provide a display device, including the above light-emitting device.

The beneficial effect of the present invention: through forming a gap between the bottom electrode and the limitation block, and forming a gap between the top electrode and the limitation block so that an uneven thickness region of each function layer of the light-emitting component is not located between the bottom electrode and the top electrode which are overlapped in space. Accordingly, a carrier flow having a higher current density will not pass through the uneven thickness region of each function layer so that the light-emitting property of the pixel will not be affected.

### BRIEF DESCRIPTION OF THE DRAWINGS

Through following to combine figures to describe in detail, the above, the other purposes, the features and benefits of the exemplary embodiment of the present disclosure will become clearer, wherein:

FIG. 1 is a top view of a light-emitting region defined by limitation block according to an embodiment of the present invention; and

FIG. 2 is a cross-sectional view of a light-emitting device according to an embodiment of the present invention.

### DETAILED DESCRIPTION OF THE PREFERRED EMBODIMENT

The following content combines with the drawings and the embodiment for describing the present invention in detail. It is obvious that the following embodiments are only some embodiments of the present invention. For the person of ordinary skill in the art without creative effort, the other embodiments obtained thereby are still covered by the present invention.

In the figures, in order to clearly describe some devices, layers and thickness of a region is enlarged. A same numeral indicates a same device in the entire specification and figures.

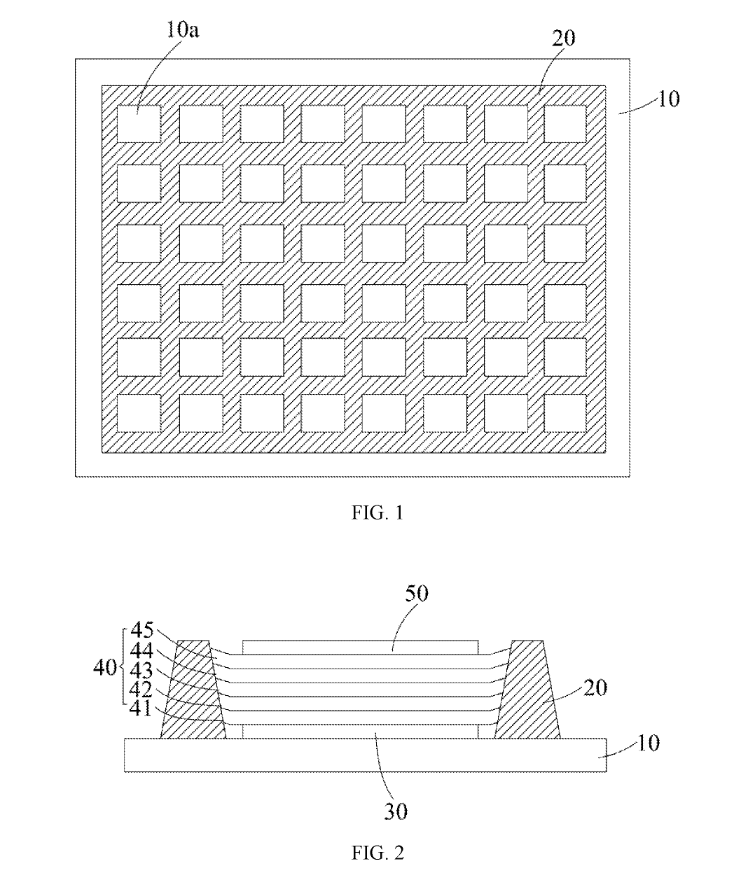

FIG. 1 is a top view of a light-emitting region defined by a limitation block according to an embodiment of the present invention.

With reference to FIG. 1, multiple limitations blocks (or called as a pixel definition layer) 20 are arranged vertically and horizontally on a substrate 10 in order to define multiple light-emitting regions 10a. Preferably, the light-emitting regions 10a are arranged as a matrix. However, the present invention is not limited here.

The following adopts one light-emitting region 10a as an example for reference. Each of the other light-emitting regions 10a is the same as the light-emitting region 10a shown following.

FIG. 2 is a cross-sectional view of a light-emitting device according to an embodiment of the present invention. It should be noted that the light-emitting device is usually used in an organic light-emitting display device or other suitable display device.

With reference to FIG. 2, the light-emitting device according to the embodiment of the present invention includes: a substrate 10, a limitation block (or called as a pixel definition layer) 20, a bottom electrode 30, a light-emitting component 40 and a top electrode 50. It should be noted that the light-emitting device of the present invention can also include other suitable elements.

The substrate 10 can be transparent or non-transparent. For observing the illumination of the light-emitting component 40 through the substrate 10, the substrate 10 has a light transmission property. In this situation, a transparent glass or a plastic material are adopted. For observing the light-emitting component 40 through the top electrode 50, the substrate 10 can be transparent, light absorbing or reflective. The material adopted includes but not limited to glass, plastic material, semiconductor material, ceramics, circuit board material or other suitable materials.

As described above, the limitation block 20 defines a light-emitting region 10a on the substrate 10. In the present embodiment, the limitation block 20 can be a single-layered structure, a double-layered structure or a multiple-layered structure formed by a hydrophobic material. The hydrophobic material can be polystyrene, polyethylene terephthalate, etc.

The bottom electrode 30 is disposed on the substrate 10 and located in the light-emitting region 10a. A gap is existed between the bottom electrode 30 and the limitation block 20. Here, the size of gap is determined by an edge climbing phenomenon of a solution on the limitation block 20 when forming the light-emitting component 40.

The bottom electrode 30 is usually disposed as an anode. The bottom electrode 30 is also a reflector. When observing the light-emitting component 40 to emit light through the substrate 10, the bottom electrode 30 can be made by a reflective metal, and the bottom electrode 30 should be thin enough such that the bottom electrode 30 is partially transparent in the wavelength of an emitting light. At this time, the bottom electrode 30 is translucent. Or, the bottom electrode 30 can be made by a transparent metal oxide such as indium tin oxide or tin oxide tin. When observing the light-emitting component 40 to emit light through the top electrode 50, the bottom electrode 30 can be made of a reflective metal, and should be thick enough such that the bottom electrode 30 is non-transparent and is a total reflection mirror.

The light-emitting component 40 is disposed on the bottom electrode 30. As an embodiment of the present invention, from the bottom electrode 30 to the top electrode 50, the light-emitting component 40 sequentially includes: a hole injection layer 41, a hole transport layer 42, a light-emitting layer 43, an electron transport layer 44 and an electron injection layer 45. It should be noted that, the light-emitting component 40 is not limited to the structure described here, and can be other suitable arbitrary light-emitting structure. Besides, the light-emitting layer 43 can be an organic light-emitting layer or a quantum dot light-emitting layer. The present invention is not limited.

Preferably, the function layers of the light-emitting component 40 can be formed by inkjet printing, and the solution for forming each function layer will form a climbing phenomenon at the limitation block 20, the size of climbing formed on the limitation block 20 by the solution of each function layer will determine the size of the gap.

The top electrode 50 is disposed on the light-emitting component 40. In the present embodiment, a gap is also existed between the top electrode 50 and the limitation block 20. Preferably, the top electrode 50 and the bottom electrode 30 are totally overlapped in the space, however, the present invention is not limited. Here, a projection of the top electrode 50 projected on the bottom electrode 30 includes a situation that a projection of the top electrode 50 projected on the bottom electrode 30 is totally overlapped with the bottom electrode 30.

The top electrode 50 is usually disposed as a cathode. The top electrode 50 is also a reflector. When observing the light-emitting component 40 to emit light through the top electrode 50, the top electrode 50 can be made by a reflective metal, and the top electrode 50 should be thin enough such that the top electrode 50 is partially transparent in the wavelength of an emitting light. At this time, the top electrode 50 is translucent. Or, the top electrode 50 can be made by a transparent metal oxide such as indium tin oxide or tin oxide tin. When observing the light-emitting component 40 to emit light through the substrate 10, the top electrode 50 can be made of a reflective metal, and should be thick enough such that the top electrode 50 is non-transparent and is a total reflection mirror.

In summary, through forming a gap between the bottom electrode 30 and the limitation block 20, and forming a gap between the top electrode 50 and the limitation block 20 so that an uneven thickness region of each function layer of the light-emitting component 40 is not located between the bottom electrode 30 and the top electrode 50 which are overlapped in space. Accordingly, a carrier flow having a higher current density will not pass through the uneven thickness region of each function layer so that the light-emitting property of the pixel will not be affected.

The above embodiments of the present invention are not used to limit the claims of this invention. Any use of the content in the specification or in the drawings of the present invention which produces equivalent structures or equivalent processes, or directly or indirectly used in other related technical fields is still covered by the claims in the present invention.

What is claimed is:

1. A light-emitting device, comprising:
a substrate;
a limitation block disposed on the substrate and used for defining a light-emitting region;
a bottom electrode disposed on the substrate and located in the light-emitting region, wherein a gap is existed between the bottom electrode and the limitation block;
a light-emitting component disposed on the bottom electrode; and
a top electrode disposed on the light-emitting component.

2. The light-emitting device according to claim 1, wherein, a projection of the top electrode projected on the bottom electrode is within the bottom electrode.

3. The light-emitting device according to claim 1, wherein, from the bottom electrode to the top electrode, the light-emitting component sequentially includes: a hole injection layer, a hole transport layer, a light-emitting layer, an electron transport layer and an electron injection layer.

4. The light-emitting device according to claim 2, wherein, from the bottom electrode to the top electrode, the light-emitting component sequentially includes: a hole injection layer, a hole transport layer, a light-emitting layer, an electron transport layer and an electron injection layer.

5. The light-emitting device according to claim 3, wherein, the light-emitting layer is an organic light-emitting layer or a quantum dot light-emitting layer.

6. The light-emitting device according to claim 4, wherein, the light-emitting layer is an organic light-emitting layer or a quantum dot light-emitting layer.

7. The light-emitting device according to claim 1, wherein, one of the bottom electrode and the top electrode is transparent or translucent, and the other of the bottom electrode and the top electrode is non-transparent and reflective.

8. The light-emitting device according to claim 3, wherein, the hole injection layer and/or the hole transport layer and/or the light-emitting layer and/or the electron transport layer and/or the electron injection layer are made of inkjet printing method.

9. The light-emitting device according to claim 4, wherein, the hole injection layer and/or the hole transport layer and/or the light-emitting layer and/or the electron transport layer and/or the electron injection layer are made of inkjet printing method.

10. The light-emitting device according to claim 1, wherein, the limitation block is made of a hydrophobic material.

11. A display device comprising a light-emitting device, and the light-emitting device comprises:
a substrate;
a limitation block disposed on the substrate and used for defining a light-emitting region;
a bottom electrode disposed on the substrate and located in the light-emitting region, wherein a gap is existed between the bottom electrode and the limitation block;
a light-emitting component disposed on the bottom electrode; and
a top electrode disposed on the light-emitting component.
